(19) United States
(12) Patent Application Publication
(10) Pub. No.: US 2002/0075043 A1
(43) Pub. Date: Jun. 20, 2002

(54) Push-pull amplifier for use in generating a reference voltage

(75) Inventors: Eric William MacDonald, Cedar Park, TX (US); Lynn Albert Warriner, Round Rock, TX (US)

Correspondence Address: Duke W. Yee, Carstens, Yee & Cahoon, LLP, P. O. Box 802334, Dallas, TX, 75380, US

(73) Assignee: IBM Corporation

(21) Appl. No.: 09/734,373

(22) Filed: Dec. 14, 2000

(51) Int. Cl. H03B 1/00

(52) U.S. Cl. 327/108

(57) ABSTRACT

A circuit for use in generating a reference voltage. The circuit includes a first transistor having a first source, a first drain, a first gate, and a first body contact. The first body contact is connected to the first gate, and the first drain is connected to an upper voltage source. A second transistor having a second source, a second drain, a second gate, and a second body contact. The second body contact is connected to the second gate, and the second drain is connected to a lower voltage. The circuit also includes a first input connected to the first gate, and a second input connected to the second gate. An output connected to the first source and the second source.

### BACKGROUND OF THE INVENTION

1. Technical Field

The present invention relates generally to electrical circuits, and in particular to a circuit for generating a reference voltage. Still more particularly, a present invention an amplifier circuit with less sensitivity to current changes.

2. Description of Related Art

Currently, various microprocessors require a direct current (DC) reference voltage for input/output circuits within the microprocessor. Ideally, the reference voltage remains constant regardless of the load current. The reference voltage is typically generates through a two transistor in which the midpoint of is the reference voltage. This transistor stack includes an n-channel field effect transistor (NFET) and a p-channel field effect transistor (PFET). In the stack, the NFET is on top, while the PFET is on the bottom. The gates of these two field effect transistors (FETs) are set to separate DC values necessary to ensure that the output voltage is maintained at a selective value without excessive DC current flowing through the stack.

One problem with this current implementation is that the stack is unable to source a large amount of current while maintaining the DC reference voltage. Therefore, it would be advantageous to have an improved apparatus for generating a reference voltage.

### SUMMARY OF THE INVENTION

The present invention provides a circuit for use in generating a reference voltage. The circuit includes a first transistor having a first source, a first drain, a first gate, and a first body contact. The first body contact is connected to the first gate, and the first drain is connected to an upper voltage source. A second transistor having a second source, a second drain, a second gate, and a second body contact. The second body contact is connected to the second gate, and the second drain is connected to a lower voltage. The circuit also includes a first input connected to the first gate, and a second input connected to the second gate. An output connected to the first source and the second source.

The first body contact and the second body contact provide a connection to parasitic bipolar transistors. A reference voltage is generated at the output in response to the application of input voltages to the first input and the second input.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a schematic diagram of a push-pull amplifier in accordance with a preferred embodiment of the present invention;

FIG. 2 is a cross-sectional diagram of a body contacted n-channel metal-oxide-semiconductor (NMOS) silicon-on-insulator (SOI) field effect transistor (FET) in accordance with a preferred embodiment of the present invention;

FIG. 3 is a diagram of a layout a body contacted n-channel metal-oxide-semiconductor (NMOS) silicon-on-insulator (SOI) field effect transistor (FET) in accordance with a preferred embodiment of the present invention;

FIG. 4 is a graph of current/voltage curves in accordance with a preferred embodiment of the present invention; and

FIG. 5 is a graph illustrating base currents for n and p bipolar transistors in accordance with a preferred embodiment of the present invention.

### DETAILED DESCRIPTION OF THE PREFERRED EMBODIMENT

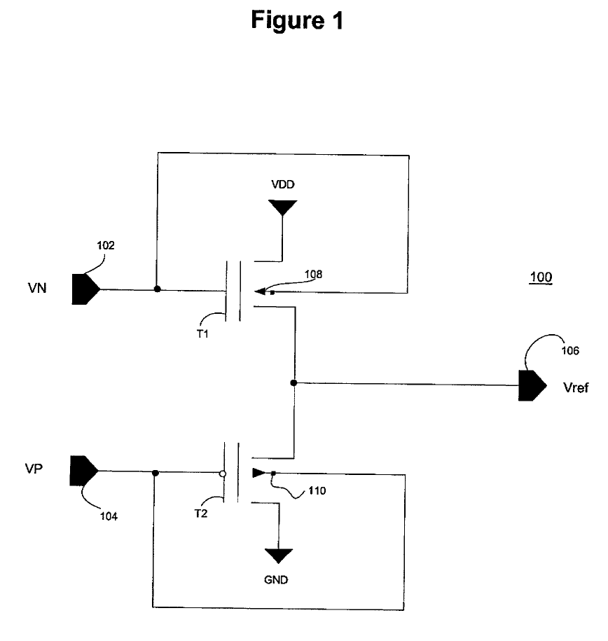

With reference now to the Figures, and in particular with reference to FIG. 1, a schematic diagram of a push-pull amplifier is depicted in accordance with a preferred embodiment of the present invention. Amplifier circuit 100 is a push-pull amplifier for use in a reference voltage circuit. Amplifier circuit 100 includes a transistor T1 and transistor T2. In the depicted examples, transistor T1 is a n-channel transistor while transistor T2 is a p-channel transistor. In the depicted examples, transistors T1 and T2 are metal-oxide-semiconductor field effect transistors (MOSFETs) formed in a silicon-on-insulator (SOI) substrate.

Transistor T1 has a drain connected to an upper voltage, upper power supply voltage VDD. Transistor T2 has its drain connected to a lower voltage, lower power supply voltage GND, which is ground in this example. The source of transistor T1 is connected to the source of transistor T2. The gate of transistor T1 is connected to input 102, while the gate of transistor T2 is connected to gate 104.

Transistors T1 and T2 are actually four-electrode devices, each having a gate, a source, a drain, and a body or substrate electrode. In the depicted examples, transistor T1 includes a body contact 108, and transistor T2 includes a body contact 110. In most applications, body contacts 108 and 110 are internally connected to the source, such that the transistor appears to be a three-electrode device. In accordance with a preferred embodiment of the present invention, the body electrodes, body electrode 108 and body electrode 110 are connected to gate electrodes. Specifically, body electrode 108 is connected to the gate transistor T1, and body electrode 110 is connected to the gate transistor T2. This connection of the body electrodes provides a connection to parasitic bipolar transistors. In these examples, the parasitic bipolar transistors are found in SOI MOSFETs.

A voltage VN is applied to input 102, while a voltage VP is applied input 104. In response to the input voltages being applied to inputs 102 and 104, an output voltage VREF is generated at output 106. The use of the parasitic bipolar transistors stiffens the output voltage VREF at output 106. This advantage is provided through using a base to the parasitic bipolar transistors, which are now active and parallel with the MOSFETs. This configuration helps source current require by the load while maintaining the reference voltage.

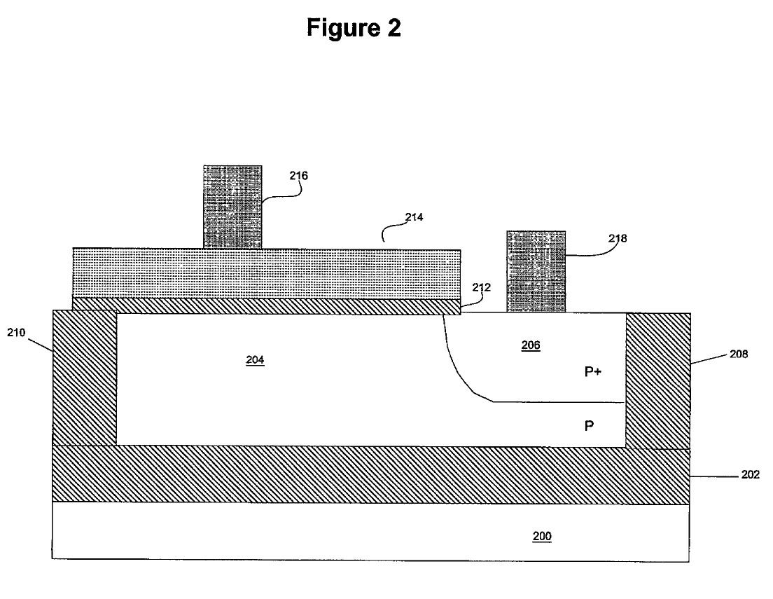

Turning next to FIG. 2, a cross-sectional diagram of a body contacted n-channel metal-oxide-semiconductor (NMOS) silicon-on-insulator (SOI) field effect transistor (FET) is depicted in accordance with a preferred embodiment of the present invention. In this example, the cross-section illustrates a cross-section of transistor T1 in FIG. 1. This cross-section is a cross-section through a body contact and a gate contact for transistor T1 in FIG. 1.

The transistor is formed in substrate 200, which is an SOI substrate. Substrate 200 includes a buried oxide layer 202. A channel 204 is formed above buried oxide layer 202. In this example, channel 204 is a p-type channel. A p+ region 206 also is formed within channel 204. Channel 204 and p+ region 206 are located between oxide regions 208 and 210. A gate for this transistor is formed through thin oxide layer 212 and poly silicon layer 214. The transistor also includes a gate contact 216 and a body contact 218. These two contacts are tied together to provide a contact to a parasitic bipolar transistor.

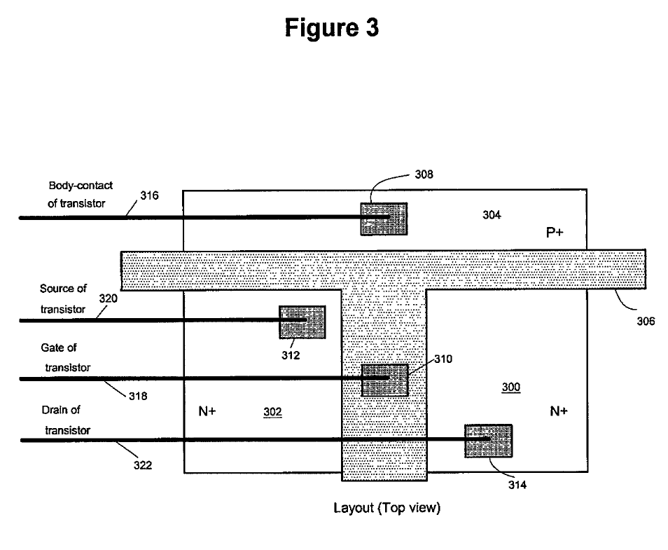

Turning next to FIG. 3, a diagram of a layout a body contacted n-channel metal-oxide-semiconductor (NMOS) silicon-on-insulator (SOI) field effect transistor (FET) is depicted in accordance with a preferred embodiment of the present invention. The layouts illustrates in FIG. 3 is that of transistor T1 in FIG. 1. The transistor, in these examples, includes the following active regions: n+ region 300, n+ region 302, and p+ region 304. The transistor also includes a poly silicon region 306. A body contact electrode 308, a gate electrode 310, a source electrode 312, and a drain electrode 314 are present. These electrodes are connected to metal lines 316, 318, 320 and 322 respectively.

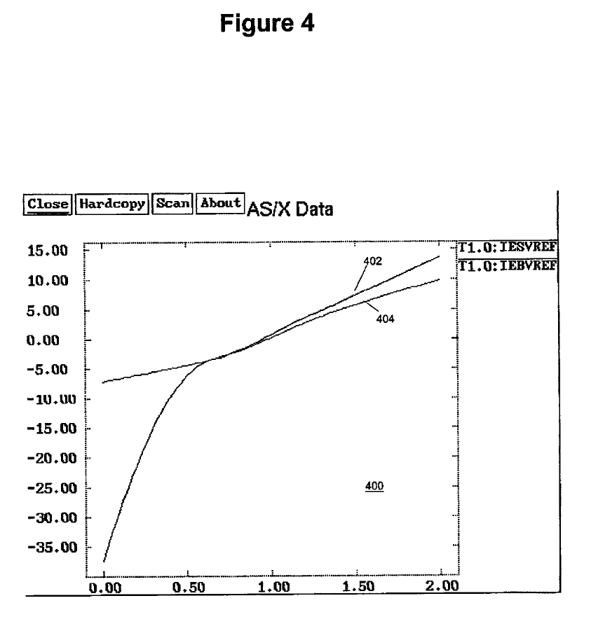

With reference now to FIG. 4, a graph of current/voltage curves is depicted in accordance with a preferred embodiment of the present invention. For reference, an ideal reference would be a straight vertical line at the intended reference voltage (˜1.0 volts in this case), so that for any value of current, the voltage would remain unchanged.

Graph 400 illustrates a IESVREF curve 402 and a IEBVREF curve 404. The x-axis represents voltage, while the y-axis represents current. IESVREF curve 402 illustrates data for an amplifier circuit according to the present invention, while IEBVREF curve 404 illustrates data for a currently known amplifier circuit in which the body contacts are not connected to the gates.

In graph 400, the two curves converge around one volt (the reference value). In this region, both current values are dominated by the MOSFET devices. Beyond the range of 0.6 to 1.4 volts, the bipolar devices are activated, dramatically increasing current for the proposed case. In this implementation, the MOSFETs are used to establish a bias point. The bipolar devices only activate when the current demand cause the output voltage to swing beyond a certain limit. The advantage of the present invention is that the bias currents are low and the response of the amplifier is sequenced based upon the demand for current.

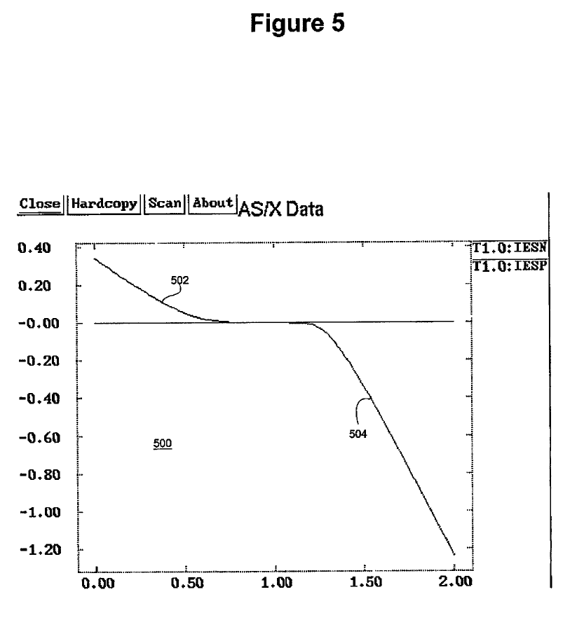

Turning next to FIG. 5, a graph illustrating base currents for n and p bipolar transistors is depicted in accordance with a preferred embodiment of the present invention. Graph 500 includes a curve 502 and a curve 504. Graph 500 illustrates the current going into the base of the parasitic bipolar transistor connected to each of the FETs. This diagram illustrates that the requirements for the amplifier of the present invention are negligible. In particular, curve 502 represents an n-channel transistor and curve 504 represents a p-channel transistor both in the amplifier circuit of the present invention.

Thus, the circuit of the present invention provides an approved mechanism for maintaining a constant reference voltage over different current loads. This advantage is achieved in these examples by connecting the body contact of a transistor to its gate. This connection provides a connect to a parasitic bipolar transistor, which aides in sourcing the current requires by the load placed on a circuit while maintaining the reference voltage close to the ideal reference voltage.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A circuit comprising:
a first transistor having a first source, a first drain, a first gate, and a first body contact, wherein the first body contact is connected to the first gate and wherein the first drain is connected to an upper voltage source
a second transistor having a second source, a second drain, a second gate, and a second body contact, wherein the second body contact is connected to the second gate and wherein the second drain is connected to a lower voltage;
a first input connected to the first gate;
a second input connected to the second gate; and
an output connected to the first source and the second source.

2. The circuit of claim 1, wherein the first input is connected to a first voltage, the second input is connected to a second voltage, and a reference voltage is generated at the output.

3. The circuit of claim 2, wherein the first transistor and second transistor are field effect transistors.

4. The circuit of claim 3, wherein the field effect transistors are metal oxide field effect transistors.

5. The circuit of claim 1, wherein the first body contact provides a connection to a parasitic bipolar transistor.

6. The circuit of claim 1, wherein the second body contact provides a connection to a parasitic bipolar transistor.

7. The circuit of claim 1, wherein the circuit is formed on a silicon-on-insulator substrate.

8. The circuit of claim 1, wherein the first transistor is a n-channel field effect transistor and the second transistor is a p-channel field effect transistor.

9. The circuit of claim 1, wherein the circuit is an amplifier circuit for generating a reference voltage.

10. The circuit of claim 1, wherein the reference voltage is generated at the output.

11. A amplifier circuit comprising:
a n-channel transistor having a first source, a first drain, a first gate, and a first body contact to a first parasitic bipolar transistor, wherein the first body contact is connected to the first gate, wherein the first gate is connected to a first input, the first drain is connected to an upper voltage source; and
a p-channel second transistor having a second source, a second drain, a second gate, and a second body contact to a second parasitic bipolar transistor, wherein the second body contact is connected to the second gate, the second drain is connected to a lower voltage, wherein second gate is connected, and wherein the p-channel transistor is connected to the n-channel transistor in push-pull configuration having an output for a reference voltage, which is generated in response to input voltages applied to the first gate and the second gate.

12. The amplifier circuit of claim 11, wherein the amplifier circuit is formed on a silicon-on-insulator substrate.

13. The amplifier circuit of claim 11, wherein the n-channel transistor is a n-channel field effect transistor and the p-channel transistor is a p-channel field effect transistor.

14. The amplifier circuit of claim 11, wherein the n-channel transistor and the p-channel transistor are metal oxide field effect transistors.
